(19) United States
(12) Patent Application Publication
(10) Pub. No.: US 2013/0285076 A1
(43) Pub. Date: Oct. 31, 2013

(54) LIGHT EMITTING DIODE DEVICE

(71) Applicants: Heng LIU, Sunnyvale, CA (US); Jinn Kong SHEU, Tainan City (TW)

(72) Inventors: Heng LIU, Sunnyvale, CA (US); Jinn Kong SHEU, Tainan City (TW)

(73) Assignee: PHOSTEK, INC., Taipei City (TW)

(21) Appl. No.: 13/532,599

(22) Filed: Jun. 25, 2012

(30) Foreign Application Priority Data
Apr. 27, 2012 (TW) 101115289

(51) Int. Cl. H01L 33/08

(52) U.S. Cl. 257/88; 257/E33.012

(57) ABSTRACT

A light emitting diode (LED) device includes at least one stacking LED unit. The stacking LED unit includes a plurality of epitaxial structures interleaved with tunnel junctions. For a given predetermined input power, the plurality of epitaxial structures may reduce an operating current density of the stacking LED unit as compared to an LED unit with a single epitaxial structure and the same horizontal size. The reduced operating current density approaches a quantum efficiency peak. Additionally, for a given predetermined input power, the stacking LED unit may operate in a current density interval corresponding to a quantum efficiency within 20% decrement of the quantum efficiency peak.

### BACKGROUND OF THE INVENTION

1. Field of the Invention

The present invention generally relates to a light emitting diode (LED) device, and more particularly to a stacking LED unit of the LED device.

2. Description of Related Art

Internal quantum efficiency (IQE) is an index that is frequently used to measure luminous efficiency of a light emitting diode (LED). A unit of the IQE is often expressed as a percentage (%) to represent a ratio of transformed output photons to input electrons/holes (or current). The LED usually has an IQE peak, denoting a maximum luminous efficiency, at a low current density (e.g., 1-10 A/cm²). The IQE, however, droops when the current density increases.

Conventional LEDs are operated in a high current density interval (e.g., 30-50 A/cm²), instead of the IQE peak, due to concerns in decrease in chip area and cost and high luminescence. As the efficiency of transforming electricity to light is low in the high current density interval, a substantial portion of electricity is transformed into heat, which wastes energy, and the lifetime of the LEDs is shortened. In addition, further schemes may be required to dissipate the generated heat, which may increase overall cost and volume.

In order to overcome the IQE droop phenomenon at the high current density, improved LED structures are proposed, for example, in U.S. Pat. No. 7,843,060 entitled “Droop-free high output light emitting devices and methods of fabricating and operating same.” The improved LED structures, however, possess a complicated structure, for example, having increased epitaxial layers with lengthened fabrication time and higher cost.

Therefore, a need has arisen to propose a novel LED device with an uncomplicated structure, a simplified process, and a low cost for overcoming disadvantages of the IQE droop phenomenon.

### SUMMARY OF THE INVENTION

In certain embodiments, a light emitting diode (LED) device includes a stacking LED unit for raising luminous efficiency and/or lowering cost.

In certain embodiments, the LED device includes at least one stacking LED unit, which includes a plurality of epitaxial structures and at least one tunnel junction. Each epitaxial structure includes an n-side nitride semiconductor layer, an active layer, and a p-side nitride semiconductor layer. Each tunnel junction is located between two adjacent epitaxial structures. In certain embodiments, a quantum efficiency of at least one of the epitaxial structures droops as an operating current density increases above a predetermined current density. The epitaxial structure has a quantum efficiency peak at an operating current density that is smaller than the predetermined current density. In some embodiments, for a given predetermined input power, the plurality of epitaxial structures reduces the operating current density of the stacking LED unit as compared to an operating current density of an LED unit made of a single epitaxial structure with the same horizontal size, and wherein the reduced operating current density approaches the operating current density at the quantum efficiency peak. In some embodiments, for a given predetermined input power, the stacking LED unit operates in a current density interval corresponding to the quantum efficiency within 20% decrement of the quantum efficiency peak.

### BRIEF DESCRIPTION OF THE DRAWINGS

FIG. 1 shows a sectional view of an embodiment of a stacking LED unit.

FIG. 2 shows an embodiment of an internal quantum efficiency (IQE) curve.

FIG. 3 shows an internal quantum efficiency (IQE) curve and an associated operating current density interval.

FIG. 4 shows a perspective diagram illustrating an embodiment of an LED device.

### DETAILED DESCRIPTION OF THE INVENTION

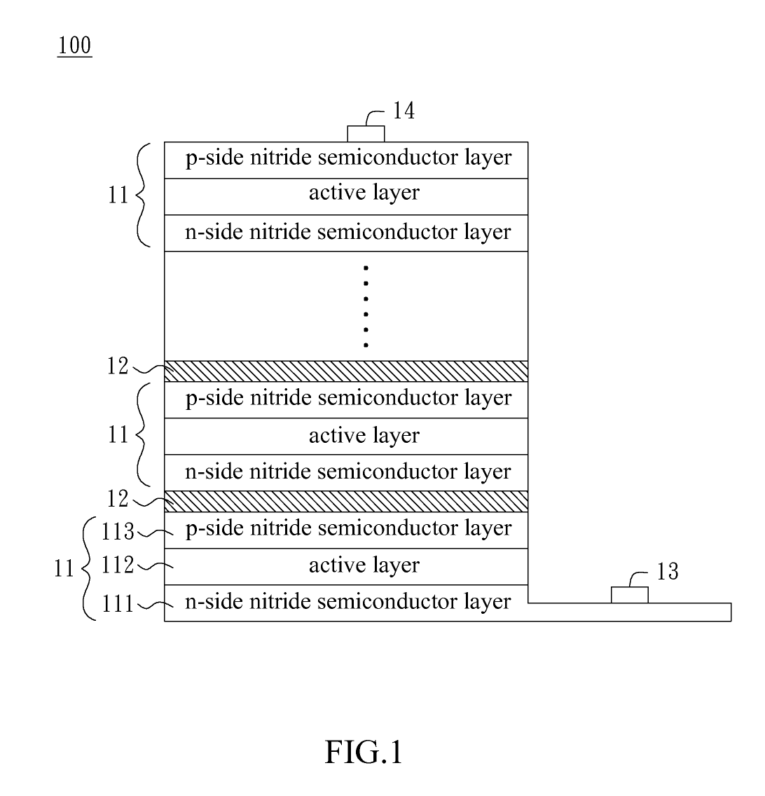

FIG. 1 shows a sectional view of an embodiment of stacking LED unit 100. Stacking LED unit 100 includes a plurality of epitaxial structures 11 interleaved with tunnel junctions 12. Each tunnel junction 12 vertically stacks up adjacent epitaxial structures 11 in an epitaxial process to form stacking LED unit 100. In certain embodiments, epitaxial structure 11 includes n-side nitride semiconductor layer 111, active layer 112, and p-side nitride semiconductor layer 113. Active layer 112 is deposited between n-side nitride semiconductor layer 111 and p-side nitride semiconductor layer 113. Tunnel junction 12 is deposited between p-side nitride semiconductor layer 113 of one epitaxial structure 11 and n-side nitride semiconductor layer 111 of an adjacent epitaxial structure 11.

Tunnel junction 12 may be formed using a high doping process, a polarization induced process, or other processes suitable for forming layers capable of generating a tunneling effect. Tunnel junction 12 may include a single film or multiple films. In some embodiments, stacking LED unit 100, shown in FIG. 1, may include first electrode 13 and second electrode 14. First electrode 13 is formed on a surface of n-side nitride semiconductor layer 111 of a bottom epitaxial structure 11. For example, first electrode 13 may be formed on an extension of n-side nitride semiconductor layer 111 of the bottom epitaxial structure 11, as shown in FIG. 1. Second electrode 14 is formed on a surface of p-side nitride semiconductor layer 113 of a top epitaxial structure 11.

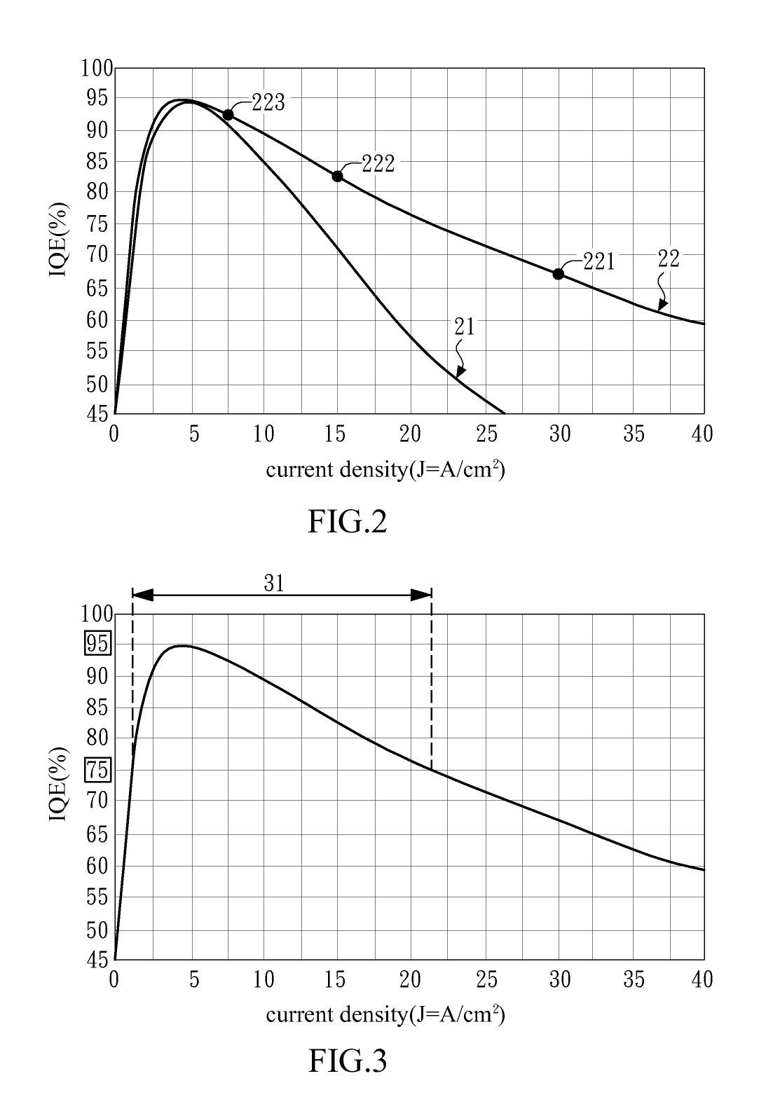

FIG. 2 shows an embodiment of an internal quantum efficiency (IQE) curve. The curve represents a relationship between an IQE (in %) and a current density (in A/cm²) of a single epitaxial structure 11. As shown in FIG. 2, both IQE curve 21 and IQE curve 22 possess a droop phenomenon. Taking IQE curve 21 for example, an IQE of 95% is reached at the peak of the curve when a current density is equal to about 5 A/cm², and an IQE of 45% is reached when a current density is approximately equal to 25 A/cm². As a result, IQE curve 21 has a falling rate of about 2.5% (A/cm²)⁻¹ (=(95-45)/(25-5)). Taking IQE curve 22 for example, an IQE of 95% is reached at the peak of the curve when a current density is equal to about 5 A/cm², and an IQE of 60% is reached when a current density is approximately equal to 40 A/cm². As a result, IQE curve 22 has a falling rate of about 1% (A/cm²)⁻¹ (=(95-60)/(40-5)). It may be observed, between IQE curve 21 and IQE curve 22, that curve 21 with a large falling rate is defined as a strong droop curve, and curve 22 with a small falling rate is defined as a weak droop curve. In certain embodiments, the IQE falling rate of a (single) epitaxial structure 11 may be, but not necessarily, equal to or higher than 1% (A/cm²)⁻¹. In other words, epitaxial structure 11 has an IQE droop rate equal to or higher than that of curve 22.

An external quantum efficiency (EQE) is defined as a product of the IQE multiplied by a light-extraction efficiency (LEE), that is, EQE=IQE*LEE. The EQE (in %) with respect to a current density (in A/cm²) may generally be represented by an inclined curve that is similar to an inclined curve representing the IQE with respect to a current density, supposing that the LEE (e.g., 50-90% in one embodiment) remains constant irrespective of change in operation conditions.

In certain embodiments, it is assumed that an IQE peak (or maximum) corresponds to a current density B and an IQE within 50% decrement of the IQE peak corresponds to a current density A. The values A and B therefore have the following relationship: A>B ≧0.1 A.

Because of the relationship between the internal (or external) quantum efficiency and the current density, as shown in FIG. 2, a total voltage of the stacking LED unit 100 made of a plurality of stacked epitaxial structures 11, shown in FIG. 1, may increase for a given predetermined input power provided that the epitaxial structures each have approximately the same operating voltage (e.g., 3 volt). Compared to a conventional LED made of a single epitaxial structure with the same input power and the same horizontal size, the embodiment of stacking LED unit 100 has a decreased operating current density that approaches an internal (or external) quantum efficiency peak. As a result, stacking LED unit 100 has a higher internal (or external) quantum efficiency for a given predetermined input power. In other words, stacking LED unit 100 has a higher efficiency of transforming electricity to light than the conventional single LED. The higher efficiency may decrease or prevent the heat dissipation problem. In certain embodiments, stacking LED unit 100 has an operating current density smaller than 20 A/cm². Compared to a conventional LED having an operating current density higher than 30 A/cm², stacking LED unit 100 has a higher internal (or external) quantum efficiency; and, at the same time, the stacking LED unit may maintain the same horizontal size as the conventional LED with the single epitaxial structure. Thus, the chip cost will not be substantively increased.

The relationship among the current density, the internal (or external) quantum efficiency, and the amount of the epitaxial structures 11 will be described below in accordance with IQE curve 22 of FIG. 2. For a given predetermined input power of 90 V·A/cm² and an operating voltage of 3 volts for each epitaxial structure 11, a current density of 30 A/cm² may be reached, at operating point 221, if a single epitaxial structure 11 is used. The current density becomes half the original current density that is, 15 A/cm² (at operating point 222) and the total voltage doubles (e.g., 6 volts), if two epitaxial structures 11 are used. The current density becomes one fourth the original current density, that is, 7.5 A/cm² (at operating point 223) and the total voltage quadruples (e.g., 12 volts), if four epitaxial structures 11 are used.

In certain embodiments, for a given predetermined input power, stacking LED unit 100 made of a plurality of epitaxial structures 11 may operate in current density interval 31 corresponding to an internal (or external) quantum efficiency within 20% decrement of the IQE (or EQE) peak, as demonstrated in the IQE curve shown in FIG. 3. For example, stacking LED unit 100 may operate in a current density interval corresponding to an IQE (or EQE) within 15% decrement of the IQE (or EQE) peak. Moreover, for a given predetermined input power and the same operating voltage (e.g., 3 volts) of each epitaxial structure 11, the number of epitaxial structures 11 in stacking LED unit 100 is determined based on the operating current density.

In some embodiments, the IQE peak of epitaxial structure 11 is equal to or higher than 60%. For example, the IQE peak of epitaxial structure 11 may be equal to or higher than 70%.

Some methods for increasing the IQE (or EQE) peak are exemplified below. A first method for increasing the IQE (or EQE) peak is to decrease defect density of n-side nitride semiconductor layer 111. As the defect density of n-side nitride semiconductor layer 111 decreases, the IQE (or EQE) peak may accordingly increase. A second method for increasing the IQE (or EQE) peak is to enhance crystalline quality of active layer 112, for example, by increasing its Shockley-Read-Hall (SRH) lifetime. As the crystalline quality of active layer 112 enhances, the IQE (or EQE) peak may accordingly increase. A third method for increasing the IQE (or EQE) peak is to use a polarization matched barrier in active layer 112. A fourth method for increasing the IQE (or EQE) peak is to not use an electron blocking layer (EBL), for example, between active layer 112 and second electrode 14, thereby increasing electrons injection. A fifth method for increasing the IQE (or EQE) peak is to use a graded well layer in active layer 112. A sixth method for increasing the IQE (or EQE) peak is to use a well layer with a superlattice structure in active layer 112. The superlattice structure may be formed by alternating two sub-layers of different materials or by alternating two sub-layers of the same material but different constitutions.

The methods for increasing the IQE (or EQE) peak as discussed above may generally improve the IQE (or EQE) droop problem. Using these methods to increase the IQE (or EQE) peak may, however, come at a cost of complicating epitaxial structure 11. As in certain embodiments, stacking LED unit 100 is operated at a low current density (e.g., lower than 20 A/cm²), the improvement in the droop problem that affects the IQE only at high current density may bring no substantial advantages. Accordingly, in some embodiments, a scheme of simplified structure may maintain (or even increase) the IQE (or EQE) peak, even though it may possibly deteriorate the droop problem, to shorten process time and reduce associated cost. A method of maintaining (or even increasing) the IQE (or EQE) peak while simplifying the structure is to controllably reduce the number of quantum wells (QWs) in active layer 112. For example, the number of quantum wells (QWs) may be equal to or less than 6. In certain embodiments, the total number of quantum wells (QWs) of stacking LED unit 100 is equal to or less than 30.

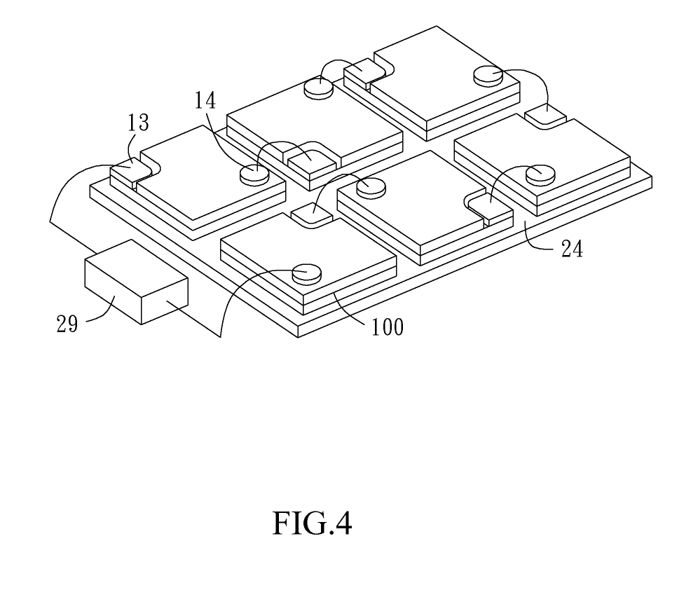

FIG. 4 shows a perspective diagram illustrating an embodiment of an LED device. The LED device includes a plurality of stacking LED units 100 that are arranged on substrate 24 in an array form. The LED device, as shown in FIG. 4, may therefore be called an LED array. Adjacent stacking LED units 100 may be electrically coupled through first electrode 13 and/or second electrode 14. For example, the electrodes may be coupled via a solder wire or an interconnect line to serially and/or parallelly connect a sequence of the stacking LED units. Taking the serially connected sequence as an example, first electrode 13 of the most front stacking LED unit 100 and second electrode 14 of the most rear stacking LED unit 100 in the sequence are respectively connected to two ends of power supply 29.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A light emitting diode (LED) device including at least one stacking LED unit, wherein the stacking LED unit comprises:
a plurality of epitaxial structures, wherein each epitaxial structure includes an n-side nitride semiconductor layer, an active layer, and a p-side nitride semiconductor layer; and
at least one tunnel junction, wherein each tunnel junction is located between two said epitaxial structures that are adjacent to each other;
wherein a quantum efficiency of at least one of the epitaxial structures droops as an operating current density increases above a predetermined current density, and the epitaxial structure has a quantum efficiency peak at an operating current density that is smaller than the predetermined current density; and
wherein, for a given predetermined input power, the plurality of epitaxial structures reduce the operating current density of the stacking LED unit as compared to an operating current density of an LED unit made of a single epitaxial structure with the same horizontal size, and wherein the reduced operating current density approaches the operating current density at the quantum efficiency peak.

2. The LED device of claim 1, wherein the predetermined current density is 20 A/cm².

3. The LED device of claim 1, wherein the quantum efficiency of the epitaxial structure droops at a falling rate that is equal to or higher than 1% (A/cm²)⁻¹.

4. The LED device of claim 1, wherein the quantum efficiency peak corresponds to a current density B, the quantum efficiency within 50% decrement of the quantum efficiency peak corresponds to a current density A, and the epitaxial structure conforms to: A>B≧0.1 A.

5. The LED device of claim 1, wherein the quantum efficiency peak is an internal quantum efficiency peak, which is equal to or higher than 60%.

6. The LED device of claim 1, wherein the quantum efficiency peak increases as a defect density of the n-side nitride semiconductor layer decreases.

7. The LED device of claim 1, wherein a number of quantum wells in the active layer of at least one of the epitaxial structures is equal to or smaller than 6.

8. The LED device of claim 1, wherein a number of total quantum wells in the stacking LED unit is equal to or smaller than 30.

9. The LED device of claim 1, wherein the LED device comprises a plurality of the stacking LED units that are arranged on a substrate in an array form, wherein each said stacking LED unit comprises a first electrode and a second electrode, wherein the stacking LED units adjacent to each other are electrically coupled through the first electrode and/or the second electrode to serially and/or parallelly connect the stacking LED units.

10. The LED device of claim 1, wherein, for the given predetermined input power, the total voltage of the plurality of the epitaxial structures is higher than the operating voltage of each epitaxial structure.

11. A light emitting diode (LED) device including at least one stacking LED unit, wherein the stacking LED unit comprises:
a plurality of epitaxial structures, wherein each epitaxial structure includes an n-side nitride semiconductor layer, an active layer, and a p-side nitride semiconductor layer; and
at least one tunnel junction, wherein each tunnel junction is located between two said epitaxial structures that are adjacent to each other;
wherein a quantum efficiency of at least one of the epitaxial structures droops as an operating current density increases above a predetermined current density, and the epitaxial structure has a quantum efficiency peak at an operating current density that is smaller than the predetermined current density; and
wherein, for a given predetermined input power, the stacking LED unit operates in a current density interval corresponding to the quantum efficiency within 20% decrement of the quantum efficiency peak.

12. The LED device of claim 11, wherein the predetermined current density is 20 A/cm².

13. The LED device of claim 11, wherein the quantum efficiency of the epitaxial structure droops at a falling rate that is equal to or higher than 1% (A/cm²)⁻¹.

14. The LED device of claim 11, wherein a number of the epitaxial structures is determined based on the operating current density interval.

15. The LED device of claim 11, wherein, for the given predetermined input power, the total voltage of the plurality of the epitaxial structures is higher than the operating voltage of each epitaxial structure.

16. The LED device of claim 11, wherein the quantum efficiency peak is an internal quantum efficiency peak, which is equal to or higher than 60%.

17. The LED device of claim 11, wherein the quantum efficiency peak increases as a defect density of the n-side nitride semiconductor layer decreases.

18. The LED device of claim 11, wherein a number of quantum wells in the active layer of at least one of the epitaxial structures is equal to or smaller than 6.

19. The LED device of claim 11, wherein a number of total quantum wells in the stacking LED unit is equal to or smaller than 30.

20. The LED device of claim 11, wherein the LED device comprises a plurality of the stacking LED units that are arranged on a substrate in an array form, wherein each said stacking LED unit comprises a first electrode and a second electrode, wherein the stacking LED units adjacent to each other are electrically coupled through the first electrode and/or the second electrode to serially and/or parallelly connect the stacking LED units.

21. The LED device of claim 1, wherein the tunnel junction is formed in an epitaxial process to be coupled to the two epitaxial structures that are adjacent to each other.

22. The LED device of claim 11, wherein the tunnel junction is formed in an epitaxial process to be coupled to the two epitaxial structures that are adjacent to each other.
